(19) United States
(12) Patent Application Publication
(10) Pub. No.: US 2025/0125149 A1
(43) Pub. Date: Apr. 17, 2025

(54) METHOD OF FABRICATING SEMICONDUCTOR DEVICES WITH ISOLATED SUPERLATTICE STRUCTURES

(71) Applicant: ATOMERA INCORPORATED, LOS GATOS, CA (US)

(72) Inventors: MAREK HYTHA, BROOKLINE, MA (US); RICHARD BURTON, PHOENIX, AZ (US); NYLES WYNN CODY, TEMPE, AZ (US); ROBERT J. MEARS, WELLESLEY, MA (US); HIDEKI TAKEUCHI, SAN JOSE, CA (US); KEITH DORAN WEEKS, CHANDLER, AZ (US)

(21) Appl. No.: 18/915,816

(22) Filed: Oct. 15, 2024

Related U.S. Application Data
(60) Provisional application No. 63/590,515, filed on Oct. 16, 2023.

(51) Int. Cl. H01L 21/265; H01L 29/15

(52) U.S. Cl. CPC H01L 21/26533; H10D 62/8163

(57) ABSTRACT

A method for making a semiconductor device may include implanting non-semiconductor atoms into a localized region of a semiconductor layer, and forming a superlattice on the semiconductor layer over the localized region. The superlattice may include a stacked groups of layers, with each group of layers including stacked base semiconductor monolayers defining a base semiconductor portion, and at least one monolayer of the non-semiconductor atoms constrained within a crystal lattice of adjacent base semiconductor portions. The method may also include performing a thermal treatment to cause non-semiconductor atoms from the superlattice to be displaced, and to cause non-semiconductor atoms from the localized region to migrate into the superlattice and replace at least some of the displaced non-semiconductor atoms.

### RELATED APPLICATIONS

This application claims the benefit of U.S. provisional application Ser. No. 63/590,515 filed Oct. 16, 2023, which is hereby incorporated herein in its entirety by reference.

### TECHNICAL FIELD

The present disclosure generally relates to semiconductor devices, and, more particularly, to approaches for fabricating semiconductor devices with enhanced semiconductor materials.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO₂/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2, 347, 520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A method for making a semiconductor device may include implanting non-semiconductor atoms into a localized region of a semiconductor layer, and forming a superlattice on the semiconductor layer over the localized region. The superlattice may include a plurality of stacked groups of layers, with each group of layers comprising a plurality of stacked base semiconductor monolayers defining a base semiconductor portion, and at least one monolayer of the non-semiconductor atoms constrained within a crystal lattice of adjacent base semiconductor portions. The method may also include performing a thermal treatment to cause non-semiconductor atoms from the superlattice to be displaced, and to cause non-semiconductor atoms from the localized region to migrate into the superlattice and replace at least some of the displaced non-semiconductor atoms.

In an example embodiment, forming the superlattice may comprise forming the superlattice over the localized region and extending laterally outward from the localized region. Furthermore, the method may also include amorphizing portions of the superlattice that extend laterally beyond the localized region prior to performing the thermal treatment. By way of example, amorphizing may comprise implanting at least one of Si, Ar, Ne, Xe, C, F and Ge. More particularly, implanting may comprise implanting at a dosage in a range of 5×10¹⁴-1×10¹⁶/cm², for example. In accordance with another example implementation, forming the superlattice may comprise selectively forming the superlattice over the localized region.

In an example implementation, the method may further include forming a first device overlying the superlattice and a second device overlying an adjacent portion of the semiconductor layer after performing the thermal treatment. By way of example, the base semiconductor monolayers may comprise silicon, and the non-semiconductor atoms may comprise oxygen atoms.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIGS. 4-6 are a series of schematic cross-sectional diagrams illustrating a method for making a semiconductor device including a superlattice in accordance with an example embodiment.

FIG. 7 is a schematic cross-sectional diagram illustrating what would happen to the superlattice shown in FIG. 5 if the method illustrated in FIGS. 4-6 was not used.

FIGS. 8 and 9 are SIMS plots of oxygen concentration vs. depth for an example implementation of the method of FIGS. 4-6.

FIG. 10 is a schematic cross-sectional diagram of a semiconductor device fabricated using the approach of FIGS. 4-6 which includes MOSFETs with and without superlattice layers.

FIG. 11 is a flow diagram of an example method for making a semiconductor device using the approach illustrated in FIGS. 4-6.

FIG. 12 is a flow diagram of an alternative embodiment of the method of FIG. 11.

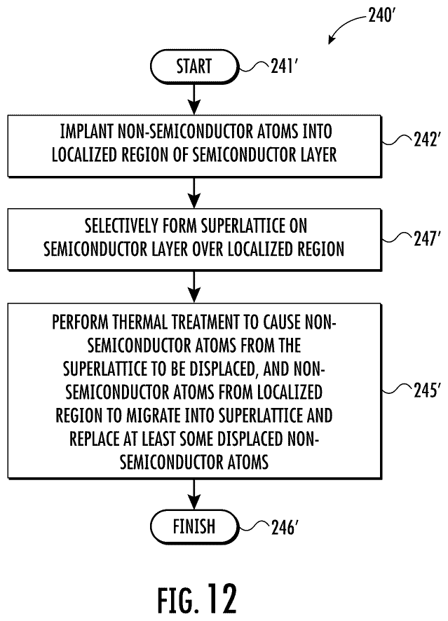

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers and that this thereby leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stoichiometric SiOₓ. Alternately, the trapping of interstitials by MST layers may reduce the concentration of interstitial silicon proximate to the Si—SiO interface, reducing the tendency to form sub-stoichiometric SiOₓ. Sub-stoichiometric SiO₂ at the Si—SiO₂ interface is known to exhibit inferior insulating properties relative to stoichiometric SiO₂. Reducing the amount of sub-stoichiometric SiOₓ at the interface may more effectively confine free carriers (electrons or holes) in the silicon, and thus improve the mobility of these carriers due to electric fields applied parallel to the interface, as is standard practice in field-effect-transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as will be discussed further below.

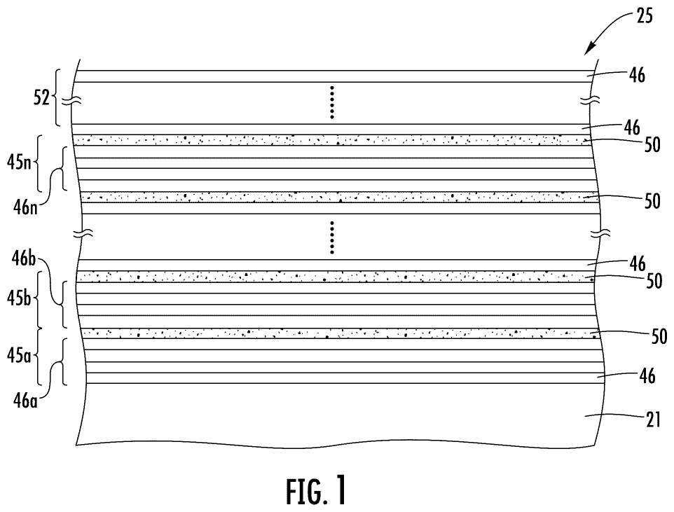

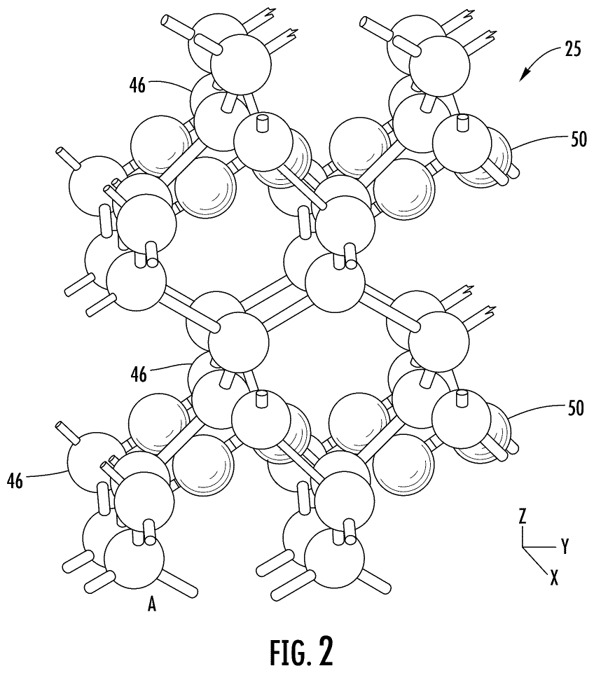

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that non-semiconductor monolayers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present embodiments, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably, between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the embodiments may be readily adopted and implemented, as will be appreciated by those skilled in the art.

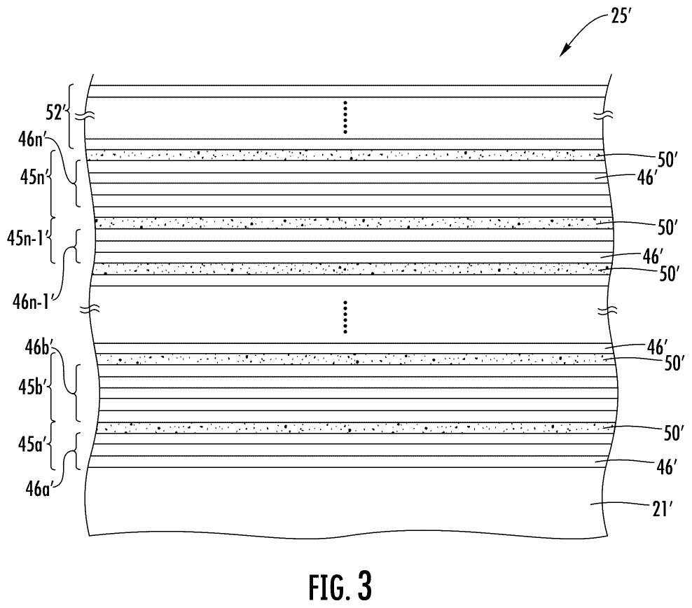

Referring now additionally to FIG. 3, another embodiment of a superlattice 25′ in accordance with the embodiments having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

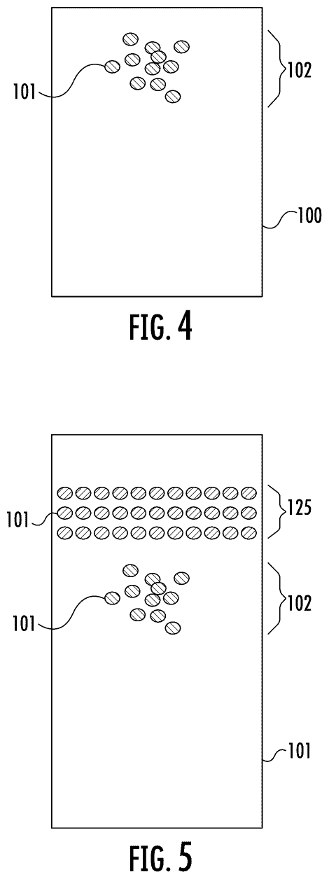

Turning to FIGS. 4-6, an approach for selectively fabricating MST films such as those described above that are laterally segmented from one another, and related devices, are now described. By way of background, as discussed further in U.S. Pat. No. 10, 109, 479, which is also from the present Applicant and is hereby incorporated herein its entirety by reference, relatively high temperature processing (annealing) steps performed after MST film formation can in some instances cause non-semiconductor atoms, such as oxygen, to disassociate from the non-semiconductor monolayers and migrate away from the superlattice. If this occurs in sufficient quantity, it will result in there no longer being a superlattice, but instead only bulk semiconductor material in its place. The present approach advantageously increases the thermal stability of the MST film in this regard by introducing an additional oxygen and/or nitrogen source to compensate for non-semiconductor (e.g., oxygen) loss during thermal processing.

In the illustrated approach, non-semiconductor atoms 101 (e.g., oxygen or others listed above) are implanted in a semiconductor (e.g., silicon) layer in an implant region 102 (FIG. 4). In some embodiments, these non-semiconductor atoms (e.g., oxygen) are the same as those that will be used in the subsequent formation of the MST superlattice 125 (FIG. 5), because they will replace atoms of the same type exiting the superlattice. By way of example, the implant may be of a dosage that is close to that used for the subsequently formed MST layer 125, e.g., within a dose range of 1×10¹⁴-5×10¹⁵/cm², for example.

In some embodiments, other atoms (e.g., nitrogen) may optionally be implanted in the region 102 in addition to the non-semiconductor atoms 101. In accordance with one example, nitrogen atoms may be included along with oxygen atoms. In some embodiments, nitrogen may be implanted without oxygen, notwithstanding oxygen being the non-semiconductor used in the MST superlattice 125. The nitrogen implant range would be similar to the oxygen dose range noted above. For more information on the incorporation of nitrogen with MST-oxygen films, see U.S. Pat. Pub. No. 2020/0135489, which is also assigned to the present Applicant and is hereby incorporated herein in its entirety by reference.

As noted above, MST films 125 which utilize oxygen as the non-semiconductor material (MST-O) may lose oxygen during thermal processing. Oxygen atoms 101 introduced as a species into the silicon layer 100 in the implantation region 102 during processing will diffuse and compensate for oxygen flux away from the MST layer 125. Nitrogen introduced by implantation as noted above may optionally be used to assist in stabilizing oxygen atoms within the MST film 125, for example.

This may provide several technical benefits. For example, MST stability may be increased across the entire wafer over a baseline MST deposition process. Moreover, with tuning of the subsequent thermal processing and patterned implantation of these species, some devices or some portion thereof may have more or less effect from MST doping profile control.

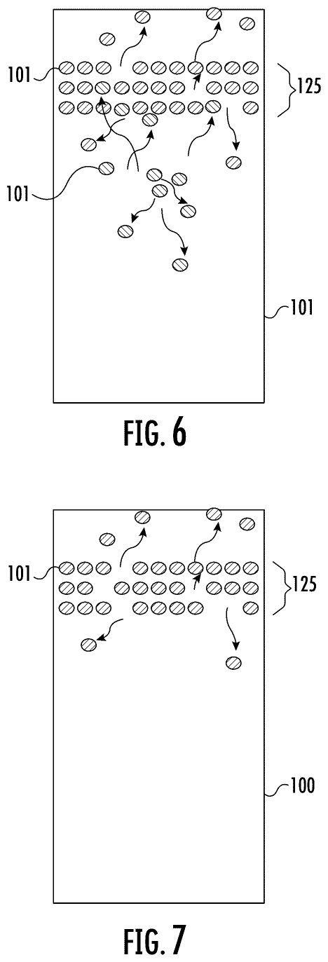

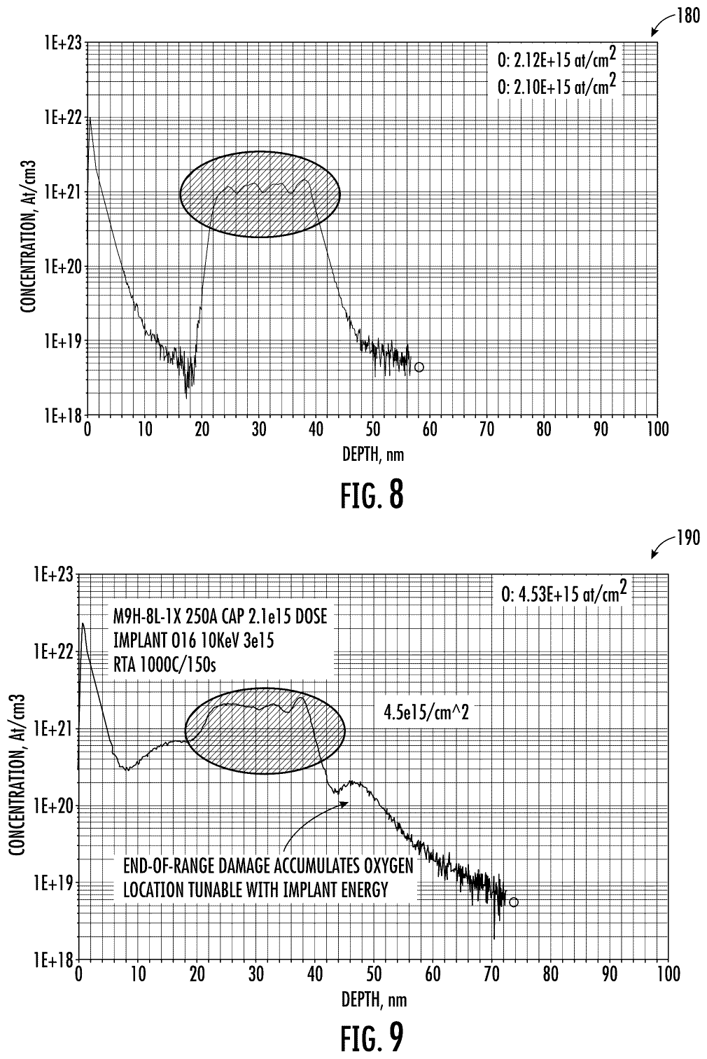

As seen in FIG. 6, the implanted oxygen atoms 101 replace some of the oxygen atoms within the MST film 125 during high temperature thermal processing. By way of contrast, FIG. 7 shows what would otherwise happen to an MST film 125 if there was no implanted oxygen atoms 101 to replace some of the displaced or “evaporated” oxygen atoms from the MST film. The SIMS profile 180 of FIG. 8 shows how in an example implementation the oxygen dose essentially doubles from 2.1×10¹⁵ to 4.5×10¹⁵/cm² in an MST film 125 after the above-noted implant and anneal steps. Moreover, the SIMS profile 190 of FIG. 9 demonstrates that end of range (EOR) damage accumulates oxygen, and a depth of EOR may advantageously be tuned to help minimize any negative impact to semiconductor devices, as will be appreciated by those skilled in the art.

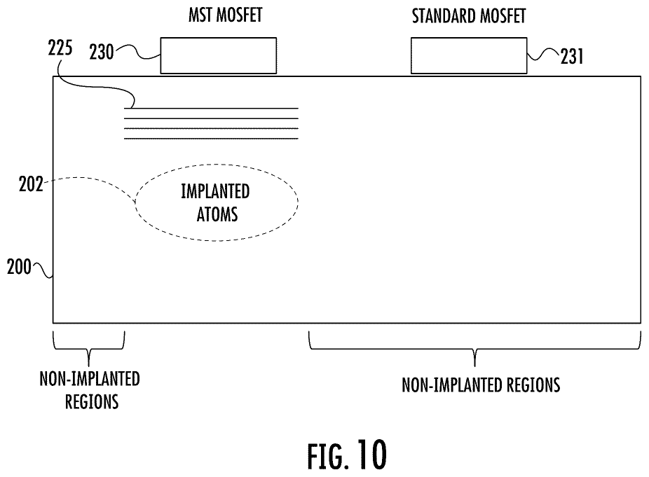

Referring additionally to FIG. 10, while the above-noted approach may be used to increase the thermal stability of a blanket MST film across an entire wafer or substrate, in other embodiments with tuning of the subsequent thermal processing and patterned implantation of these species, specific devices or portions of devices may be tailored through MST doping profile control so that MST films 225 will remain in desired locations, but not in others. That is, MST doping profile control may be utilized to create laterally-segmented MST films 225 from a blanket film deposition on a semiconductor layer or substrate 200, to thereby provide MST films only in the particular locations where they are desired in a given semiconductor device (i.e., where the implant regions 202 are located). As such, different metal oxide semiconductor field effect transistors (MOSFETs) 230, 231 may be fabricated in the semiconductor layer 200 with (MST MOS) and without (standard MOS) an MST film 225, respectively. Various examples of MST MOS devices 230 which may be fabricated using this approach are provided in U.S. Pat. No. 10, 847, 618 to Takeuchi et al., which is also from the present Applicant and is hereby incorporated herein in its entirety by reference.

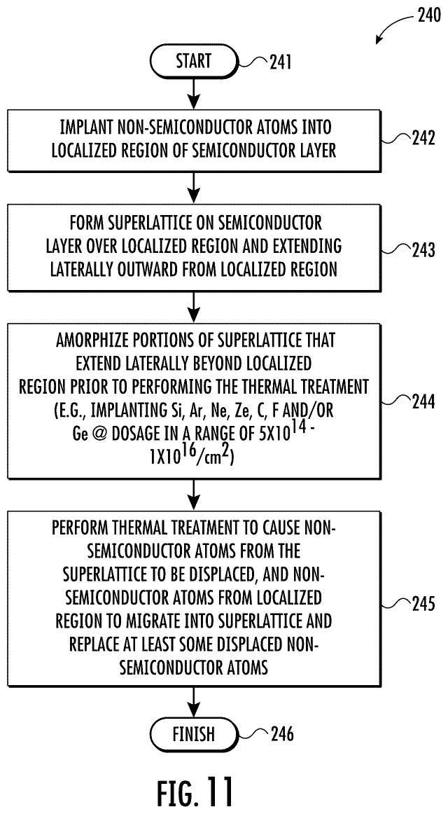

Referring to the flow diagram 240 of FIG. 11, an example approach to fabricating laterally segmented MST films from a blanket MST deposition uses a “damage” and neutralization process. More particularly, beginning at Block 241, after implanting the non-semiconductor (e.g., O and optionally N) into the localized regions 102 of the semiconductor layer 100 (Block 242), blanket MST film 125 deposition is performed (Block 243). The MST film 125 is thereafter disordered or amorphized in desired locations where no MST film is to be present in the final device, and thereby made less stable to oxygen retention during thermal processing, at Block 244. By way of example, one of Si/Ar/Ne/Xe/C/F/Ge, or a combination of these species, for example, are implanted at a sufficient dose (e.g., 5×10¹⁴-1×10¹⁶) to amorphize the MST film 125 in regions where no MST film is to be present. In some embodiments, a relatively high dose of F may be used to neutralize As activation, for example. Thereafter, the thermal treatment (e.g., rapid thermal anneal, RTA) may be performed, causing non-semiconductor atoms 101 to be displaced from the MST layer 125, while implanted atoms from the implant region 102 migrate into the MST layer and replace displaced atoms, as discussed further above (Block 245). The method of FIG. 11 illustratively concludes at Block 246.

More particularly, as discussed above, an MST superlattice is an ordered structure (e.g., ordered silicon monolayers). If the ordering is significantly disturbed, the thermal stability of the MST film 125 during subsequent thermal processing may be substantially reduced. Since implants may be patterned, the MST structure may be modified laterally, enabling MST films 125 effectively to be limited to certain devices or to certain parts of devices, in turn enabling positional doping profile control, as noted above.

Referring to the flow diagram 240′ of FIG. 11, another example approach to fabricating laterally segmented MST films is provided. In the illustrated approach, the implant and thermal treatments steps (Block 242′ and 246′) are similar to those described above. However, rather than a blanket deposition, localized MST films 125 are selectively grown (Block 247′) over corresponding implant regions 102. While this avoids the need to amorphize portions of a blanket deposition as discussed above, it would involve different masking steps, so one approach or the other may be more desirable depending on factors such as the chamber(s) and/or tools being used, the types of devices being fabricated, etc., as will be appreciated by those skilled in the art.

The foregoing approaches may advantageously allow MST technology to be applied to select devices, yet without impacting standard devices on a chip, as seen in FIG. 10. This may advantageously help reduce IC redesign efforts and design kit redevelopment by adding only MST device enhancements where specifically desired. Furthermore, MST technology may also be applied to a desired portion of a device to provide additional flexibility in 2D doping profile engineering to enhance device performance (e.g., for high voltage devices such as eDMOS or LDMOS) with a relatively straightforward processes integration. Moreover, the above-described implementations provide a relatively low-cost process for IC manufacturing with enhanced MST technology in desired locations.

Many modifications and other embodiments of the invention will come to the mind of one skilled in the art having the benefit of the teachings presented in the foregoing descriptions and the associated drawings. Therefore, it is understood that the present disclosure is not to be limited to the specific embodiments disclosed, and that modifications and embodiments are intended to be included within the scope of the appended claims.

1. A method for making a semiconductor device comprising:
implanting non-semiconductor atoms into a localized region of a semiconductor layer;
forming a superlattice on the semiconductor layer over the localized region, the superlattice comprising a plurality of stacked groups of layers, each group of layers comprising a plurality of stacked base semiconductor monolayers defining a base semiconductor portion, and at least one monolayer of the non-semiconductor atoms constrained within a crystal lattice of adjacent base semiconductor portions; and
performing a thermal treatment to cause non-semiconductor atoms from the superlattice to be displaced, and to cause non-semiconductor atoms from the localized region to migrate into the superlattice and replace at least some of the displaced non-semiconductor atoms.

2. The method of claim 1 wherein forming the superlattice comprises forming the superlattice over the localized region and extending laterally outward from the localized region.

3. The method of claim 2 comprising amorphizing portions of the superlattice that extend laterally beyond the localized region prior to performing the thermal treatment.

4. The method of claim 3 wherein amorphizing comprises implanting at least one of Si, Ar, Ne, Xe, C, F and Ge.

5. The method of claim 3 wherein implanting comprises implanting at a dosage in a range of 5×10¹⁴-1×10¹⁶/cm².

6. The method of claim 1 wherein forming the superlattice comprises selectively forming the superlattice over the localized region.

7. The method of claim 1 further comprising forming a first device overlying the superlattice and a second device overlying an adjacent portion of the semiconductor layer after performing the thermal treatment.

8. The method of claim 1 wherein the base semiconductor monolayers comprise silicon.

9. The method of claim 1 wherein the non-semiconductor atoms comprise oxygen atoms.

10. A method for making a semiconductor device comprising:
implanting non-semiconductor atoms into a localized region of a semiconductor layer;
forming a superlattice on the semiconductor layer over the localized region, the superlattice comprising a plurality of stacked groups of layers and extending laterally outward from the localized region, each group of layers comprising a plurality of stacked base semiconductor monolayers defining a base semiconductor portion, and at least one monolayer of the non-semiconductor atoms constrained within a crystal lattice of adjacent base semiconductor portions;
performing a thermal treatment to cause non-semiconductor atoms from the superlattice to be displaced, and to cause non-semiconductor atoms from the localized region to migrate into the superlattice and replace at least some of the displaced non-semiconductor atoms; and
forming a first device overlying the superlattice and a second device overlying an adjacent portion of the semiconductor layer after performing the thermal treatment.

11. The method of claim 10 comprising amorphizing portions of the superlattice that extend laterally beyond the localized region prior to performing the thermal treatment.

12. The method of claim 11 amorphizing comprises implanting at least one of Si, Ar, Ne, Xe, C, F and Ge.

13. The method of claim 11 wherein implanting comprises implanting at a dosage in a range of 5×10¹⁴-1×10¹⁶/cm².

14. A method for making a semiconductor device comprising:
implanting oxygen atoms into a localized region of a semiconductor layer;
forming a superlattice on the semiconductor layer over the localized region, the superlattice comprising a plurality of stacked groups of layers, each group of layers comprising a plurality of stacked base silicon monolayers defining a base silicon portion, and at least one monolayer of oxygen atoms constrained within a crystal lattice of adjacent base silicon portions; and
performing a thermal treatment to cause oxygen atoms from the superlattice to be displaced, and to cause oxygen atoms from the localized region to migrate into the superlattice and replace at least some of the displaced oxygen atoms.

15. The method of claim 14 wherein forming the superlattice comprises forming the superlattice over the localized region and extending laterally outward from the localized region.

16. The method of claim 15 comprising amorphizing portions of the superlattice that extend laterally beyond the localized region prior to performing the thermal treatment.

17. The method of claim 16 wherein amorphizing comprises implanting at least one of Si, Ar, Ne, Xe, C, F and Ge.

18. The method of claim 16 wherein implanting comprises implanting at a dosage in a range of 5×10¹⁴-1×10¹⁶/cm².

19. The method of claim 14 wherein forming the superlattice comprises selectively forming the superlattice over the localized region.

20. The method of claim 14 further comprising forming a first device overlying the superlattice and a second device overlying an adjacent portion of the semiconductor layer after performing the thermal treatment.
